(19) United States
(12) Patent Application Publication
(10) Pub. No.: US 2016/0307981 A1
(43) Pub. Date: Oct. 20, 2016

(54) ORGANIC LIGHT-EMITTING DIODE DISPLAY

(71) Applicant: Samsung Display Co., Ltd., Yongin-si (KR)

(72) Inventor: Jin Goo Jung, Seongnam-si (KR)

(21) Appl. No.: 15/098,178

(22) Filed: Apr. 13, 2016

(30) Foreign Application Priority Data
Apr. 14, 2015 (KR) 10-2015-0052483

(51) Int. Cl. H01L 27/32

(52) U.S. Cl. CPC H01L 27/3262; H01L 27/3276

(57) ABSTRACT

An organic light-emitting diode (OLED) display is disclosed. In one aspect, the OLED display includes a substrate and a first thin film transistor (TFT) formed over the substrate and including a first active pattern, wherein the first active pattern includes a channel region and a first gate electrode formed over the channel region. The OLED display further includes a gate insulating layer formed over the first active pattern and including a plurality of openings formed adjacent to the channel region of the first active pattern and an OLED electrically connected to the first active pattern.

### CROSS-REFERENCE TO RELATED APPLICATION

This application claims priority to and the benefit of Korean Patent Application No. 10-2015-0052483 filed in the Korean Intellectual Property Office on Apr. 14, 2015, the entire contents of which are incorporated herein by reference.

### BACKGROUND

1. Field

The described technology generally relates to an organic light-emitting diode display.

2. Description of the Related Technology

Typical types of flat panel display are organic light-emitting diode (OLED), liquid crystal display (LCD), and plasma display panel (PDP), for example.

OLED technology uses thin film transistors formed on a substrate and an OLED connected to the thin film transistors to form a pixel circuit.

Recently, high resolution OLED displays with an increased pixel per inch (ppi) have been manufactured to meet market demand.

The above information disclosed in this Background section is only for enhancement of understanding of the background of the inventive technology and therefore it can contain information that does not constitute the prior art that is already known in this country to a person of ordinary skill in the art.

### SUMMARY OF CERTAIN INVENTIVE ASPECTS

One inventive aspect relates to an OLED display that increases grays of light emitted from OLEDs by increasing a driving range of a gate voltage Vgs of a driving thin film transistor connected to an OLED of each pixel even though a high resolution OLED display in which a pixel per inch (ppi) is increased is manufactured.

Another aspect is an OLED display including: a substrate; a first thin film transistor positioned on the substrate and including a first active pattern including a channel region and a first gate electrode positioned on the channel region of the first active pattern; a gate insulating layer covering the first active pattern and including a plurality of open holes neighboring to the channel region of the first active pattern; and an OLED connected to the first active pattern.

One or more of the plurality of open holes can be overlapped with the channel region.

Some of the plurality of open holes can be overlapped with the channel region, and the others thereof do not overlap the channel region.

The gate insulating layer can cover the first gate electrode.

The plurality of open holes can include one or more contact holes exposing the first gate electrode.

The number of contact holes can be plural, and one or more of the plurality of contact holes can be overlapped with the channel region.

The number of contact holes can be plural, and some of the plurality of contact holes can be overlapped with the channel region, and the others thereof do not overlap the channel region.

The OLED display can further include: a second thin film transistor including a second active pattern connected to one end portion of the first active pattern and a second gate electrode positioned on the second active pattern; a data line positioned on the gate insulating layer and connected to the second active pattern; a third thin film transistor including a third active pattern connected to the other end portion of the first active pattern and a third gate electrode positioned on the third active pattern; and a gate bridge positioned on the gate insulating layer, connecting between the third active pattern and the first gate electrode, and directly connected to the first gate electrode through the contact hole.

The number of contact holes can be plural, and the gate bridge can include: one stem part connected to the third active pattern; and a plurality of branch parts branched from the stem part into each of the plurality of contact holes to each contact the first gate electrode through each of the plurality of contact holes.

The OLED display can further include: a first scan line positioned on the second active pattern, traversing each of the second active pattern and the third active pattern, and connected to the second gate electrode and the third gate electrode; and a driving power supply line neighboring to the data line on the first scan line, traversing the first scan line, and connected to the first active pattern.

The OLED display can further include: a capacitor electrode connected to the driving power supply line, positioned on the first gate electrode, and overlapped with the first gate electrode to form a capacitor together with the first gate electrode.

Each of the first gate electrode and the capacitor electrode can be made of a metal.

The OLED display can further include: a fourth thin film transistor connected to the third active pattern and including a fourth active pattern connected to the first gate electrode through the gate bridge and a fourth gate electrode positioned on the fourth active pattern; a second scan line positioned on the fourth active pattern, traversing the fourth active pattern, and connected to the fourth gate electrode; and an initialization power supply line connected to the fourth active pattern.

The OLED display can further include: a fifth thin film transistor including a fifth active pattern connecting between the first active pattern and the driving power supply line and a fifth gate electrode positioned on the fifth active pattern; a sixth thin film transistor including a sixth active pattern connecting between the first active pattern and the OLED and a sixth gate electrode positioned on the sixth active pattern; and a light emitting control line positioned on each of the fifth active pattern and the sixth active pattern, traversing each of the fifth active pattern and the sixth active pattern, and connected to each of the fifth gate electrode and the sixth gate electrode.

The OLED display can further include: a seventh thin film transistor including a seventh active pattern connected to the fourth active pattern and a seventh gate electrode positioned on the seventh active pattern; and a third scan line positioned on the seventh active pattern, traversing the seventh active pattern, and connected to the seventh gate electrode.

The gate insulating layer can be positioned between the first active pattern and the first gate electrode.

The plurality of open holes do not overlap the channel region.

The first active pattern can be heat-treated in a state in which the first active pattern is covered with the gate insulating layer.

The channel region of the first active pattern can have a form in which the channel region of the first active pattern is linearly extended.

The channel region of the first active pattern can have a form in which the channel region of the first active pattern is bent once or more and extended.

Another aspect is an organic light-emitting diode (OLED) display comprising: a substrate; a first thin film transistor (TFT) formed over the substrate and including a first active pattern, wherein the first active pattern includes a channel region and a first gate electrode formed over the channel region; a gate insulating layer formed over the first active pattern and including a plurality of openings formed adjacent to the channel region of the first active pattern; and an OLED electrically connected to the first active pattern.

In the above OLED display, at least one of the openings overlap the channel region. In the above OLED display, at least one of the openings does not overlap the channel region. In the above OLED display, the gate insulating layer covers the first gate electrode. In the above OLED display, the openings include one or more contact holes formed over the first gate electrode. In the above OLED display, more than one of the contact holes are formed, and wherein at least one of the contact holes overlap the channel region of the first active pattern. In the above OLED display, more than one of the contact holes are formed, wherein some of the contact holes overlap the channel region, and wherein the other contact holes do not overlap the channel region.

The above OLED display further comprises: a second thin film transistor including i) a second active pattern electrically connected to a first end portion of the first active pattern and ii) a second gate electrode formed over the second active pattern; a data line formed over the gate insulating layer and electrically connected to the second active pattern; a third thin film transistor including i) a third active pattern electrically connected to a second end portion of the first active pattern and ii) a third gate electrode formed over the third active pattern; and a gate bridge formed over the gate insulating layer, configured to electrically connect the third active pattern to the first gate electrode, and directly connected to the first gate electrode through the contact hole.

In the above OLED display, more than one of the contact holes are formed, and wherein the gate bridge includes: one stem part connected to the third active pattern; and a plurality of branch parts branching from the stem part into each of the contact holes to each contact the first gate electrode via the contact holes. The above OLED display further comprises: a first scan line formed over the second and third active patterns and electrically connected to the second gate electrode and the third gate electrode; and a driving power supply line formed adjacent to the data line on the first scan line and electrically connected to the first active pattern.

The above OLED display further comprises: a capacitor electrode electrically connected to the driving power supply line, formed over the first gate electrode, and overlapping the first gate electrode to form a capacitor together with the first gate electrode. In the above OLED display, each of the first gate electrode and the capacitor electrode is formed of a metal. The above OLED display further comprises: a fourth thin film transistor electrically connected to the third active pattern and including a fourth active pattern electrically connected to the first gate electrode via the gate bridge and a fourth gate electrode formed over the fourth active pattern; a second scan line formed over the fourth active pattern and electrically connected to the fourth gate electrode; and an initialization power supply line electrically connected to the fourth active pattern.

The above OLED display further comprises: a fifth thin film transistor including i) a fifth active pattern configured to electrically connect the first active pattern to the driving power supply line and ii) a fifth gate electrode formed over the fifth active pattern; a sixth thin film transistor including i) a sixth active pattern configured to electrically the first active pattern to the OLED and ii) a sixth gate electrode formed over the sixth active pattern; and a light emitting control line formed over each of the fifth active pattern and the sixth active pattern and electrically connected to the fifth and sixth gate electrodes.

The above OLED display further comprises: a seventh thin film transistor including a seventh active pattern electrically connected to the fourth active pattern and a seventh gate electrode formed over the seventh active pattern; and a third scan line formed over the seventh active pattern and electrically connected to the seventh gate electrode.

In the above OLED display, the gate insulating layer is interposed between the first active pattern and the first gate electrode. In the above OLED display, two or more of the openings do not overlap the channel region. In the above OLED display, the gate insulating layer includes: a first gate insulating layer covering the channel region of the first active pattern and ii) second and third gate insulating layers formed over the first gate insulating layer and the first gate electrode, and wherein the openings are formed in the second and third gate insulating layers. In the above OLED display, the first active pattern further includes source and drain electrodes, and wherein the channel region of the first active pattern linearly extending from the source electrode to the drain electrode has a substantially uniform width. In the above OLED display, the channel region of the first active pattern is bent at least once.

According to at least one of the embodiments, even though a high resolution OLED display in which pixel per inch (ppi) increases the driving range of a gate voltage (Vgs) of a driving thin film transistor increases. Thus, OLED luminance can still be increased.

### BRIEF DESCRIPTION OF THE DRAWINGS

FIG. 1 is a circuit diagram showing one pixel of an OLED display according to an exemplary embodiment.

FIG. 2 is a layout view showing one pixel of the OLED display according to an exemplary embodiment.

FIG. 3 is a cross-sectional view taken along line III-III of FIG. 2.

FIG. 4 is a layout view showing one pixel of an OLED display according to another exemplary embodiment.

FIG. 5 is a layout view showing one pixel of an OLED display according to another exemplary embodiment.

FIG. 6 is a layout view showing one pixel of an OLED display according to another exemplary embodiment.

FIG. 7 is a layout view showing one pixel of an OLED display according to another exemplary embodiment.

FIG. 8 is a cross-sectional view taken along line VIII-VIII of FIG. 7.

FIG. 9 is a cross-sectional view showing an OLED display according to another exemplary embodiment.

### DETAILED DESCRIPTION OF CERTAIN INVENTIVE EMBODIMENTS

Hereinafter, several exemplary embodiments of the described technology will be described in detail with reference to the accompanying drawings so that those skilled in the art to which the described technology pertains can easily practice the described technology. However, the described technology can be implemented in various different forms and is not limited to exemplary embodiments provided herein.

Portions unrelated to the description will be omitted in order to obviously describe the described technology, and similar components will be denoted by the same reference numerals throughout the present specification.

In addition, in several exemplary embodiments, components having the same configuration will be representatively described using the same reference numerals in an exemplary embodiment, and only components different from those of an exemplary embodiment will be described in another exemplary embodiment.

In addition, since sizes and thicknesses of the respective components shown in the accompanying drawings are arbitrarily shown for convenience of explanation, the described technology is not necessarily limited to contents shown in the accompanying drawings.

In the drawings, the thickness of layers, films, panels, regions, etc., are exaggerated for clarity. In addition, in the accompanying drawings, thicknesses of some of layers and regions have been exaggerated for convenience of explanation. It will be understood that when an element such as a layer, a film, a region, or a substrate is referred to as being “on” another element, it can be directly on another element or can have an intervening element present therebetween.

In addition, throughout the present specification, unless explicitly described to the contrary, the word “comprise” and variations such as “comprises” or “comprising”, will be understood to imply the inclusion of stated elements but not the exclusion of any other elements. In addition, throughout the specification, the word “on” does not necessarily mean that any element is positioned at an upper side based on a gravity direction, but means that any element is positioned above or below a target portion. In this disclosure, the term “substantially” includes the meanings of completely, almost completely or to any significant degree under some applications and in accordance with those skilled in the art. The term “connected” can include an electrical connection.

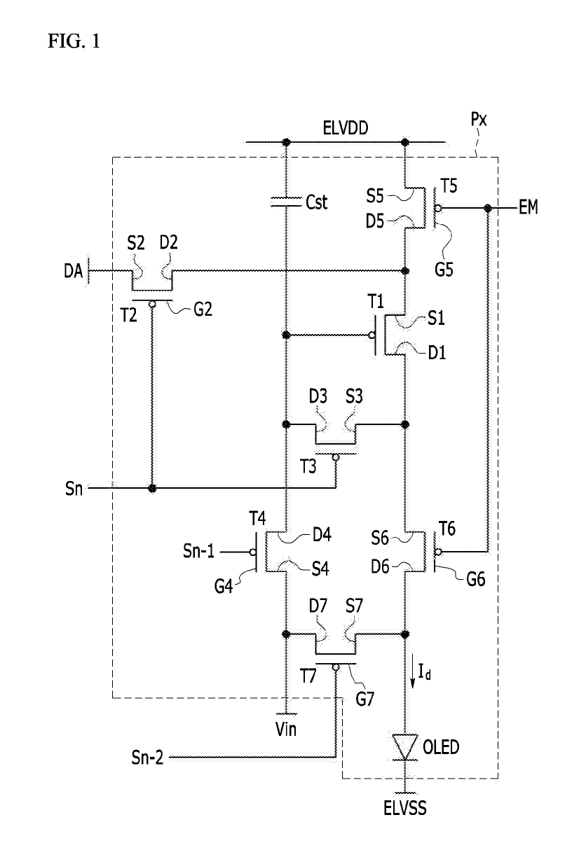

Hereinafter, an OLED display according to an exemplary embodiment will be described with reference to FIGS. 1 to 3.

Hereinafter, a pixel circuit in the OLED display according to an exemplary embodiment will be described with reference to FIG. 1. Here, the pixel can mean the minimum unit in which an image is displayed.

FIG. 1 is a circuit diagram showing one pixel of an OLED display according to an exemplary embodiment. To implement an entire display, a matrix of such pixel circuits will be formed in conjunction with driving circuitry (not shown).

As shown in FIG. 1, one pixel Px of the OLED display includes a plurality of thin film transistors T1, T2, T3, T4, T5, T6, and T7, a plurality of wirings Sn, Sn-1, Sn-2, EM, Vin, DA, and ELVDD selectively connected to the plurality of thin film transistors T1, T2, T3, T4, T5, T6, and T7, a capacitor Cst, and an OLED.

The plurality of thin film transistors T1, T2, T3, T4, T5, T6, and T7 include a first thin film transistor T1, a second thin film transistor T2, a third thin film transistor T3, a fourth thin film transistor T4, a fifth thin film transistor T5, a sixth thin film transistor T6, and a seventh thin film transistor T7.

A first gate electrode G1 of the first thin film transistor T1 is connected to each of a third drain electrode D3 of the third thin film transistor T3 and a fourth drain electrode D4 of the fourth thin film transistor T4. A first source electrode S1 of the first thin film transistor T1 is connected to each of a second drain electrode D2 of the second thin film transistor T2 and a fifth drain electrode D5 of the fifth thin film transistor T5. A first drain electrode D1 of the first thin film transistor T1 is connected to each a third source electrode S3 of the third thin film transistor T3 and a sixth source electrode S6 of the sixth thin film transistor T6.

A second gate electrode G2 of the second thin film transistor T2 is connected to a first scan line Sn. A second source electrode S2 of the second thin film transistor T2 is connected to a data line DA. The second drain electrode D2 is connected to the first source electrode S1 of the first thin film transistor T1.

A third gate electrode G3 of the third thin film transistor T3 is connected to the first scan line Sn. The third source electrode S3 is connected to the first drain electrode D1. The third drain electrode D3 is connected to the first gate electrode G1.

A fourth gate electrode G4 of the fourth thin film transistor T4 is connected to a second scan line Sn-1. A fourth source electrode S4 of the fourth thin film transistor T4 is connected to an initialization power supply line Vin. The fourth drain electrode D4 is connected to the first gate electrode G1.

A fifth gate electrode G5 of the fifth thin film transistor T5 is connected to a light emitting control line EM. A fifth source electrode S5 of the fifth thin film transistor T5 is connected to a driving power supply line ELVDD. The fifth drain electrode D5 is connected to the first source electrode S1.

A sixth gate electrode G6 of the sixth thin film transistor T6 is connected to the light emitting control line EM. The sixth source electrode S6 is connected to the first drain electrode D1 of the first thin film transistor T1.

A seventh gate electrode G7 of the seventh thin film transistor T7 is connected to a third scan line Sn-2. A seventh source electrode S7 of the seventh thin film transistor T7 is connected to the OLED. A seventh drain electrode D7 of the seventh thin film transistor T7 is connected to the fourth source electrode S4 of the fourth thin film transistor T4.

The plurality of wirings include the first scan line Sn transferring a first scan signal to each of the second gate electrode G2 and the third gate electrode G3. The second scan line Sn-1 transfers a second scan signal to the fourth gate electrode G4, and the third scan line Sn-2 transfers a third scan signal to the seventh gate electrode G7. The light emitting control line EM transfers a light emitting control signal to each of the fifth gate electrode G5 and the sixth gate electrode G6, the data line DA transfers a data signal to the second source electrode S2, and the driving power supply line ELVDD supplies a driving signal to each of one electrode of the capacitor Cst and the fifth source electrode S5. The initialization power supply line Vin supplies an initialization signal to the fourth source electrode S4. Here, the data line DA and the driving power supply line ELVDD can be formed as data wirings.

The capacitor Cst includes one electrode connected to the driving power supply line ELVDD and the other electrode connected to each of the first gate electrode G1 and the third drain electrode D3 of the third thin film transistor T3.

The OLED includes a first electrode, a second electrode positioned on the first electrode, and an organic emission layer positioned between the first electrode and the second electrode. The first electrode of the OLED is connected to each of the seventh source electrode S7 and a sixth drain electrode D6, and the second electrode of the OLED is connected to a common power supply ELVSS to which a common signal is transferred.

As an example of driving the above-mentioned pixel circuit, when the third scan signal is transferred to the third scan line Sn-2 to turn on the seventh thin film transistor T7, a residual current flowing in the first electrode of the OLED flows to the fourth thin film transistor T4 through the seventh thin film transistor T7, such that unintended light emission of the OLED by the residual current flowing in the first electrode of the OLED is suppressed.

Next, when the second scan signal is transferred to the second scan line Sn-1 and the initialization signal is transferred to the initialization power supply line Vin, the fourth thin film transistor T4 is turned on, such that an initialization voltage by the initialization signal is transferred to the first gate electrode G1 and the other electrode of the capacitor Cst through the fourth thin film transistor T4. Therefore, the first gate electrode G1 and the capacitor Cst are initialized. In this case, the first thin film transistor T1 is turned on while the first gate electrode G1 being initialized.

Next, when the first scan signal is transferred to the first scan line Sn and the data signal is transferred to the data line DA, each of the second thin film transistor T2 and the third thin film transistor T3 is turned on, such that a data voltage (Vd) by the data signal is supplied to the first gate electrode G1 through the second thin film transistor T2, the first thin film transistor T1, and the third thin film transistor T3. In this case, a compensation voltage {Vd+Vth (here, Vth is a negative (−) value)}, which is the data voltage (Vd) first supplied from the data line DA less a threshold voltage (Vth) of the first thin film transistor T, is supplied to the first gate electrode G1. The compensation voltage (Vd+Vth) supplied to the first gate electrode G1 is also supplied to the other electrode of the capacitor Cst connected to the first gate electrode G1.

Next, a driving voltage (Vel) by the driving signal from the driving power supply line ELVDD is supplied to one electrode of the capacitor Cst, and the above-mentioned compensation voltage (Vd+Vth) is supplied to the other electrode of the capacitor Cst, such that electric charges corresponding to a difference between the voltages each applied to both electrodes of the capacitor Cst are stored in the capacitor Cst, thereby turning on the first thin film transistor T1 for a predetermined time.

Next, when the light emitting control signal is applied to the light emitting control line EM, each of the fifth thin film transistor T5 and the sixth thin film transistor T6 is turned on, such that the driving voltage (Vel) by the driving signal from the driving power supply line ELVDD is supplied to the first thin film transistor T1 through the fifth thin film transistor T5.

In this case, while the driving voltage (Vel) passing through the first thin film transistor T1 turned on by the capacitor Cst, a driving current I_{d} corresponding to a voltage difference between a voltage supplied to the first gate electrode G1 by the capacitor Cst and the driving voltage (Vel) flows to the first drain electrode D1 and is then supplied to the OLED through the sixth thin film transistor T6, such that the OLED emits light for a predetermined time.

Although the pixel circuit of the OLED display according to an exemplary embodiment has been configured of the first thin film transistor T1 to the seventh thin film transistor T7, the capacitor Cst, the first scan line Sn to the third scan line Sn-2, the data line DA, the driving power supply line ELVDD, and the initialization power supply line Vin, the described technology is not limited thereto. That is, a pixel circuit of an OLED display according to another exemplary embodiment can be configured of wirings including a plurality of (two or more) thin film transistors, one or more capacitors, one or more scan lines, and one or more driving power supply lines.

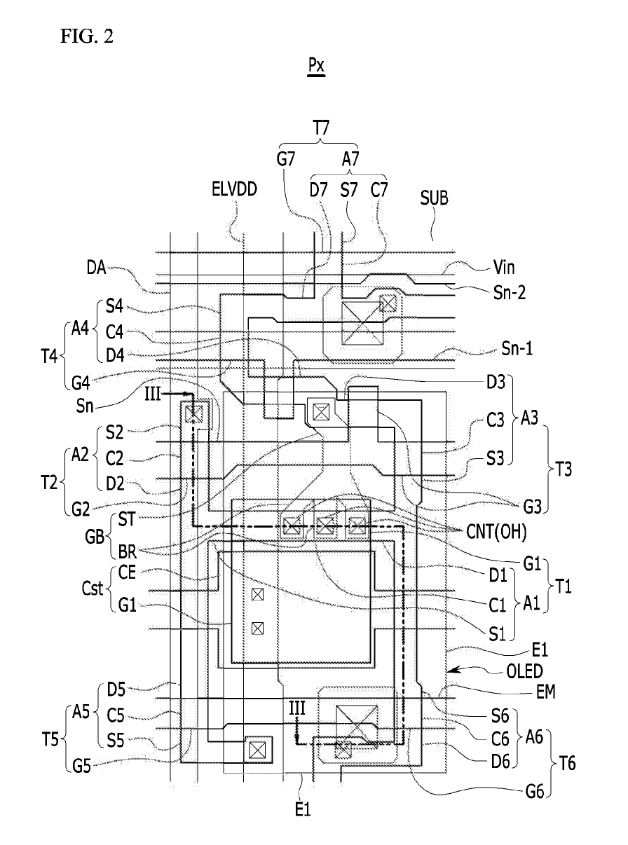

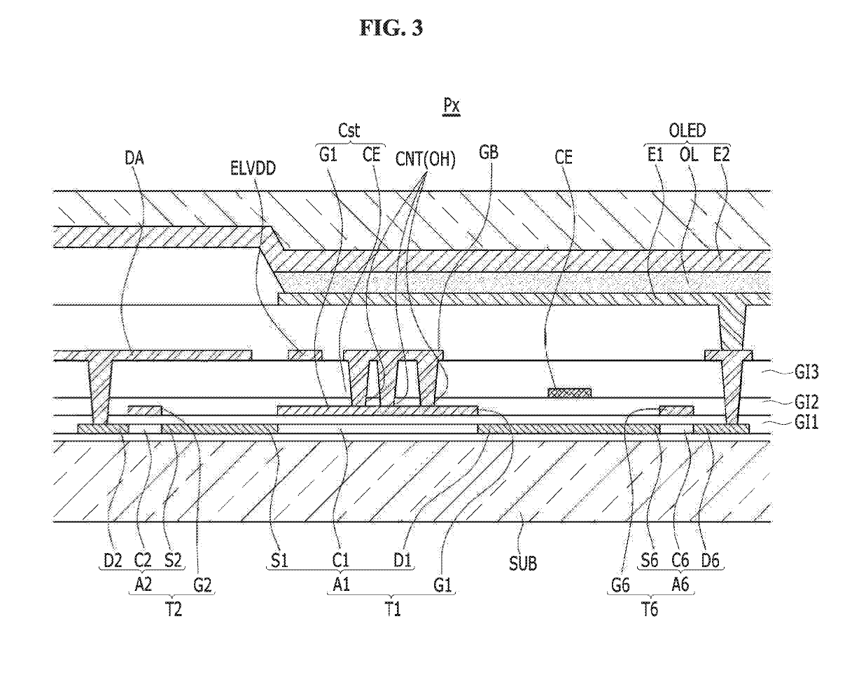

Hereinafter, a layout of the pixel of the OLED display according to an exemplary embodiment described above will be described with reference to FIGS. 2 and 3. Insulating layers can be interposed between components to be described below, or formed on different layers. These insulating layers can be inorganic insulating layers or organic insulating layers formed of a silicon nitride, a silicon oxide, or the like. In addition, these insulating layers can be formed of a single layer or plural layers.

FIG. 2 is a layout view showing one pixel of the OLED display according to an exemplary embodiment. FIG. 3 is a cross-sectional view taken along line III-III of FIG. 2.

As shown in FIGS. 2 and 3, the OLED display according to an exemplary embodiment includes a substrate SUB that can be positioned to correspond to one pixel Px, a first thin film transistor T1, a second thin film transistor T2, a third thin film transistor T3, a fourth thin film transistor T4, a fifth thin film transistor T5, a sixth thin film transistor T6, a seventh thin film transistor T7, a first gate insulating layer GI1, a second gate insulating layer GI2, a third gate insulating layer GI3, a first scan line Sn, a second scan line Sn-1, a third scan line Sn-2, a light emitting control line EM, a capacitor Cst, a data line DA, a driving power supply line ELVDD, a gate bridge GB, an initialization power supply line Vin, and an OLED.

Although the second scan line Sn-1 and the third scan line Sn-2 have been shown as the respective scan lines spaced apart from each other in FIG. 2, they are not limited thereto, but can be the same line.

The substrate SUB can be formed of glass, quartz, ceramic, sapphire, plastic, metal, or the like, and can be flexible, stretchable, rollable, or foldable. Since the substrate SUB is flexible, stretchable, rollable, or foldable, the entire OLED display can be flexible, stretchable, rollable, or foldable.

The first thin film transistor T1 is positioned on the substrate SUB, and includes a first active pattern A1 and a first gate electrode G1.

The first active pattern A1 includes a first source electrode S1, a first channel region C1, and a first drain electrode D1. The first source electrode S1 is connected to each of a second drain electrode D2 of the second thin film transistor T2 and a fifth drain electrode D5 of the fifth thin film transistor T5. The first drain electrode D1 is connected to each of a third source electrode S3 of the third thin film transistor T3 and a sixth source electrode S6 of the sixth thin film transistor T6. The first channel region C1, which is a channel region of the first active pattern A1 overlapping the first gate electrode G1, has a form in which it is linearly extended.

The first active pattern A1 can be formed of poly-silicon or an oxide semiconductor. The oxide semiconductor can include any one of an oxide of titanium (Ti), hafnium (Hf), zirconium (Zr), aluminum (Al), tantalum (Ta), germanium (Ge), zinc (Zn), gallium (Ga), tin (Sn), or indium (In), and a zinc oxide (ZnO), an indium-gallium-zinc oxide (InGaZnO₄), an indium-zinc oxide (Zn—In—O), a zinc-tin oxide (Zn—Sn—O), an indium-gallium oxide (In—Ga—O), an indium-tin oxide (In—Sn—O), an indium-zirconium oxide (In—Zr—O), an indium-zirconium-zinc oxide (In—Zr—Zn—O), an indium-zirconium-tin oxide (In—Zr—Sn—O), an indium-zirconium-gallium oxide (In—Zr—Ga—O), an indium-aluminum oxide (In—Al—O), an indium-zinc-aluminum oxide (In—Zn—Al—O), an indium-tin-aluminum oxide (In—Sn—Al—O), an indium-aluminum-gallium oxide (In—Al—Ga—O), an indium-tantalum oxide (In—Ta—O), an indium-tantalum-zinc oxide (In—Ta—Zn—O), an indium-tantalum-tin oxide (In—Ta—Sn—O), an indium-tantalum-gallium oxide (In—Ta—Ga—O), an indium-germanium oxide (In—Ge—O), an indium-germanium-zinc oxide (In—Ge—Zn—O), an indium-germanium-tin oxide (In—Ge—Sn—O), an indium-germanium-gallium oxide (In—Ge—Ga—O), a titanium-indium-zinc oxide (Ti—In—Zn—O), and a hafnium-indium-zinc oxide (Hf—In—Zn—O), which are composite oxides thereof. In the case in which the first active pattern A1 is formed of the oxide semiconductor, a separate protecting layer can be added in order to protect the oxide semiconductor vulnerable to an external environment such as a high temperature, or the like.

The first channel region C1 of the first active pattern A1 can be channel-region-doped with N-type impurities or P-type impurities, and the first source electrode S1 and the first drain electrode D1 can be spaced apart from each other with the first channel region C1 interposed therebetween and be doped with opposite type impurities to the impurities with which the first channel region C1 is doped.

The first gate electrode G1 is positioned on the first channel region C1 of the first active pattern A1 and has an island shape. The first gate electrode G1 is connected to a fourth drain electrode D4 of the fourth thin film transistor T4 and a third drain electrode D3 of the third thin film transistor T3 by gate bridges GB passing through a plurality of contact holes CNT. The first gate electrode G1 is overlapped with a capacitor electrode CE, and can serve as the other electrode of the capacitor Cst simultaneously (or concurrently) with serving as a gate electrode of the first thin film transistor T1. That is, the first gate electrode G1 forms the capacitor Cst together with the capacitor electrode (CE).

The second thin film transistor T2 is positioned on the substrate SUB, and includes a second active pattern A2 and a second gate electrode G2. The second active pattern A2 includes a second source electrode S2, a second channel region C2, and the second drain electrode D2. The second source electrode SS is connected to the data line DA through a contact hole, and the second drain electrode D2 is connected to the first source electrode S1 of the first thin film transistor T1. The second channel region C2, which is a channel region of the second active pattern A2 overlapped with the second gate electrode G2, is positioned between the second source electrode S2 and the second drain electrode D2. That is, the second active pattern A2 is connected to the first active pattern A1.

The second channel region C2 of the second active pattern A2 can be channel-region-doped with N-type impurities or P-type impurities, and the second source electrode S2 and the second drain electrode D2 can be spaced apart from each other with the second channel region C2 interposed therebetween and be doped with opposite type impurities to the impurities with which the second channel region C2 is doped. The second active pattern A2 is positioned on the same layer as a layer on which the first active pattern A1 is positioned, is formed of the same material as that of the first active pattern A1, and is formed integrally with the first active pattern A1.

The second gate electrode G2 is positioned on the second channel region C2 of the second active pattern A2, and is formed integrally with the first scan line Sn.

The third thin film transistor T3 is positioned on the substrate SUB, and includes a third active pattern A3 and a third gate electrode G3.

The third active pattern A3 includes the third source electrode S3, a third channel region C3, and the third drain electrode D3. The third source electrode S3 is connected to the first drain electrode D1, and the third drain electrode D3 is connected to the first gate electrode G1 of the first thin film transistor T1 by a gate bridge GB passing through a contact hole. The third channel region C3, which is a channel region of the third active pattern A3 overlapped with the third gate electrode G3, is positioned between the third source electrode S3 and the third drain electrode D3. That is, the third active pattern A3 connects between the first active pattern A1 and the first gate electrode G1.

The third channel region C3 of the third active pattern A3 can be channel-region-doped with N-type impurities or P-type impurities. The third source electrode S3 and the third drain electrode D3 can be spaced apart from each other with the third channel region C3 interposed therebetween and be doped with opposite type impurities to the impurities with which the third channel region C3 is doped. The third active pattern A3 is positioned on the same layer as a layer on which the first active pattern A1 and the second active pattern A2 are positioned, is formed of the same material as that of the first active pattern A1 and the second active pattern A2, and is formed integrally with the first active pattern A1 and the second active pattern A2.

The third gate electrode G3 is positioned on the third channel region C3 of the third active pattern A3, and is formed integrally with the first scan line Sn. The third gate electrode G3 is formed as a dual gate electrode, but is not limited thereto.

The fourth thin film transistor T4 is positioned on the substrate SUB, and includes a fourth active pattern A4 and a fourth gate electrode G4.

The fourth active pattern A4 includes a fourth source electrode S4, a fourth channel region C4, and the fourth drain electrode D4. The fourth source electrode S4 is connected to the initialization power supply line Vin through a contact hole, and the fourth drain electrode D4 is connected to the first gate electrode G1 of the first thin film transistor T1 by a gate bridge GB passing through the contact hole. The fourth channel region C4, which is a channel region of the fourth active pattern A4 overlapped with the fourth gate electrode G4, is positioned between the fourth source electrode S4 and the fourth drain electrode D4. That is, the fourth active pattern A4 is connected to each of the third active pattern A3 and the first gate electrode G1 simultaneously (or concurrently) with connecting between the initialization power supply line Vin and the first gate electrode G1.

The fourth channel region C4 of the fourth active pattern A4 can be channel-region-doped with N-type impurities or P-type impurities. The fourth source electrode S4 and the fourth drain electrode D4 can be spaced apart from each other with the fourth channel region C4 interposed therebetween and be doped with opposite type impurities to the impurities with which the fourth channel region C4 is doped. The fourth active pattern A4 is positioned on the same layer as a layer on which the first active pattern A1, the second active pattern A2, and the third active pattern A3 are positioned. The fourth active pattern A4 is formed of the same material as that of the first active pattern A1, the second active pattern A2, and the third active pattern A3, and is formed integrally with the first active pattern A1, the second active pattern A2, and the third active pattern A3.

The fourth gate electrode G4 is positioned on the fourth channel region C4 of the fourth active pattern A4, and is formed integrally with the second scan line Sn-1. The fourth gate electrode G4 is formed as a dual gate electrode.

The fifth thin film transistor T5 is positioned on the substrate SUB, and includes a fifth active pattern A5 and a fifth gate electrode G5.

The fifth active pattern A5 includes a fifth source electrode S5, a fifth channel region C5, and the fifth drain electrode D5. The fifth source electrode S5 is connected to the driving power supply line ELVDD through a contact hole, and the fifth drain electrode D5 is connected to the first source electrode S1 of the first thin film transistor T1. The fifth channel region C5, which is a channel region of the fifth active pattern A5 overlapped with the fifth gate electrode G5, is positioned between the fifth source electrode S5 and the fifth drain electrode D5. That is, the fifth active pattern A5 connects between the driving power supply line ELVDD and the first active pattern A1.

The fifth channel region C5 of the fifth active pattern A5 can be channel-region-doped with N-type impurities or P-type impurities. The fifth source electrode S5 and the fifth drain electrode D5 can be spaced apart from each other with the fifth channel region C5 interposed therebetween and be doped with opposite type impurities to the impurities with which the fifth channel region C5 is doped. The fifth active pattern A5 is positioned on the same layer as a layer on which the first active pattern A1, the second active pattern A2, the third active pattern A3, and the fourth active pattern A4 are positioned. The fifth active pattern A5 is formed of the same material as that of the first active pattern A1, the second active pattern A2, the third active pattern A3, and the fourth active pattern A4, and is formed integrally with the first active pattern A1, the second active pattern A2, the third active pattern A3, and the fourth active pattern A4.

The fifth gate electrode G5 is positioned on the fifth channel region C5 of the fifth active pattern A5, and is formed integrally with the light emitting control line EM.

The sixth thin film transistor T6 is positioned on the substrate SUB, and includes a sixth active pattern A6 and a sixth gate electrode G6.

The sixth active pattern A6 includes a sixth source electrode S6, a sixth channel region C6, and a sixth drain electrode D6. The sixth source electrode S6 is connected to the first drain electrode D1 of the first thin film transistor T1, and the sixth drain electrode D6 is connected to a first electrode E1 of the OLED through the contact hole CNT. The sixth channel region C6, which is a channel region of the sixth active pattern A6 overlapped with the sixth gate electrode C6, is positioned between the sixth source electrode S6 and the sixth drain electrode D6. That is, the sixth active pattern A6 connects between the first active pattern A1 and the first electrode E1 of the OLED.

The sixth channel region C6 of the sixth active pattern A6 can be channel-region-doped with N-type impurities or P-type impurities. The sixth source electrode S6 and the sixth drain electrode D6 can be spaced apart from each other with the sixth channel region C6 interposed therebetween and be doped with opposite type impurities to the impurities with which the sixth channel region C6 is doped. The sixth active pattern A6 is positioned on the same layer as a layer on which the first active pattern A1, the second active pattern A2, the third active pattern A3, the fourth active pattern A4, and the fifth active pattern A5 are positioned. The sixth active pattern A6 is formed of the same material as that of the first active pattern A1, the second active pattern A2, the third active pattern A3, the fourth active pattern A4, and the fifth active pattern A5, and is formed integrally with the first active pattern A1, the second active pattern A2, the third active pattern A3, the fourth active pattern A4, and the fifth active pattern A5.

The sixth gate electrode G6 is positioned on the sixth channel region C6 of the sixth active pattern A6, and is formed integrally with the light emitting control line EM.

The seventh thin film transistor T7 is positioned on the substrate SUB, and includes a seventh active pattern A7 and a seventh gate electrode G7.

The seventh active pattern A7 includes a seventh source electrode S7, a seventh channel region C7, and a seventh drain electrode D7. The seventh source electrode S7 is connected to a first electrode of an OLED of another pixel (not shown in FIG. 3) (that can be a pixel positioned above the pixel shown in FIG. 2). The seventh drain electrode D7 is connected to the fourth source electrode S4 of the fourth thin film transistor T4. The seventh channel region C7, which is a channel region of the seventh active pattern A7 overlapped with the seventh gate electrode G7. The seventh channel region C7 is positioned between the seventh source electrode S7 and the seventh drain electrode D7. That is, the seventh active pattern A7 connects between the first electrode of the OLED and the fourth active pattern A4.

The seventh channel region C7 of the seventh active pattern A7 can be channel-region-doped with N-type impurities or P-type impurities. The seventh source electrode S7 and the seventh drain electrode D7 can be spaced apart from each other with the seventh channel region C7 interposed therebetween and be doped with opposite type impurities to the impurities with which the seventh channel region C7 is doped. The seventh active pattern A7 is positioned on the same layer as a layer on which the first active pattern A1, the second active pattern A2, the third active pattern A3, the fourth active pattern A4, the fifth active pattern A5, and the sixth active pattern A6 are positioned. The seventh active pattern A7 is formed of the same material as that of the first active pattern A1, the second active pattern A2, the third active pattern A3, the fourth active pattern A4, the fifth active pattern A5, and the sixth active pattern A6, and is formed integrally with the first active pattern A1, the second active pattern A2, the third active pattern A3, the fourth active pattern A4, the fifth active pattern A5, and the sixth active pattern A6.

The seventh gate electrode G7 is positioned on the seventh channel region C7 of the seventh active pattern A7, and is formed integrally with the third scan line Sn-2.

The first gate insulating layer GI1, the second gate insulating layer GI2, and the third gate insulating layer GI3 are sequentially stacked on the first active pattern A1, the second active pattern A2, the third active pattern A3, the fourth active pattern A4, the fifth active pattern A5, the sixth active pattern A6, and the seventh active pattern A7. Each of the first gate insulating layer GI1, the second gate insulating layer GI2, and the third gate insulating layer GI3 can be an inorganic insulating layer or an organic insulating layer formed of silicon nitride, silicon oxide, or the like. In addition, these insulating layers can be formed of a single layer or plural layers.

The first gate insulating layer GI1 is positioned between each of the first active pattern A1, the second active pattern A2, the third active pattern A3, the fourth active pattern A4, the fifth active pattern A5, the sixth active pattern A6, and the seventh active pattern A7 and each of the first gate electrode G1, the second gate electrode G2, the third gate electrode G3, the fourth gate electrode G4, the fifth gate electrode G5, the sixth gate electrode G6, and the seventh gate electrode G7. The first gate insulating layer GI1 can prevent a short circuit between components positioned on different layers described above.

The second gate insulating layer GI2 is positioned on the first gate insulating layer GI1 to cover each of the first active pattern A1, the second active pattern A2, the third active pattern A3, the fourth active pattern A4, the fifth active pattern A5, the sixth active pattern A6, and the seventh active pattern A7. In detail, the second gate insulating layer GI2 covers each of the first gate electrode G1, the second gate electrode G2, the third gate electrode G3, the fourth gate electrode G4, the fifth gate electrode G5, the sixth gate electrode G6, and the seventh gate electrode G7. The second gate insulating layer GI2 includes a plurality of open holes OH neighboring to the first channel region C1 of the first active pattern A1. One or more of the plurality of open holes OH are overlapped with the first channel region C1, and in an exemplary embodiment, all of the plurality of open holes OH are overlapped with the first channel region C1. The plurality of open holes OH include one or more contact holes CNT exposing the first gate electrode G1, and in an exemplary embodiment, all of the plurality of open holes OH can be a plurality of contact holes CNT exposing the first gate electrode G1. One or more of the plurality of contact holes CNT can be overlapped with the first channel region C1, and in an exemplary embodiment, all of the plurality of contact holes CNT can be overlapped with the first channel region C1.

The third gate insulating layer GI3 is positioned on the second gate insulating layer GI2 to cover each of the first active pattern A1, the second active pattern A2, the third active pattern A3, the fourth active pattern A4, the fifth active pattern A5, the sixth active pattern A6, and the seventh active pattern A7. In detail, the third gate insulating layer GI3 covers the capacitor electrode CE. The third gate insulating layer GI3 includes a plurality of open holes OH neighboring to the first channel region C1 of the first active pattern A1. One or more of the plurality of open holes OH are overlapped with the first channel region C1, and in an exemplary embodiment, all of the plurality of open holes OH are overlapped with the first channel region C1. The plurality of open holes OH include one or more contact holes CNT exposing the first gate electrode G1, and in an exemplary embodiment, all of the plurality of open holes OH can be a plurality of contact holes CNT exposing the first gate electrode G1. One or more of the plurality of contact holes CNT can be overlapped with the first channel region C1, and in an exemplary embodiment, all of the plurality of contact holes CNT can be overlapped with the first channel region C1.

As described above, in an exemplary embodiment, the plurality of open holes OH are included in each of the second gate insulating layer GI2 and the third gate insulating layer GI3, and the plurality of open holes OH included in each of the second gate insulating layer GI2 and the third gate insulating layer GI3 are in communication with each other. Meanwhile, in another exemplary embodiment, the plurality of open holes OH included in each of the second gate insulating layer GI2 and the third gate insulating layer GI3 are not in communication with each other.

In addition, in an exemplary embodiment, the plurality of open holes OH are three contact holes CNT. However, the described technology is not limited thereto. That is, in another exemplary embodiment, the plurality of open holes OH can be two contact holes CNT or four or more contact holes CNT.

Each of the first gate insulating layer GI1, the second gate insulating layer GI2, and the third gate insulating layer GI3 as described above sequentially covers each of the first active pattern A1, the second active pattern A2, the third active pattern A3, the fourth active pattern A4, the fifth active pattern A5, the sixth active pattern A6, and the seventh active pattern A7. During manufacturing the OLED display, each of the first active pattern A1, the second active pattern A2, the third active pattern A3, the fourth active pattern A4, the fifth active pattern A5, the sixth active pattern A6, and the seventh active pattern A7 can be heat-treated once or more in a state in which each of the first gate insulating layer GI1, the second gate insulating layer GI2, the third gate insulating layer GI3 cover each of the first active pattern A1, the second active pattern A2, the third active pattern A3, the fourth active pattern A4, the fifth active pattern A5, the sixth active pattern A6, and the seventh active pattern A7.

The first scan line Sn is positioned on the second active pattern A2 and the third active pattern A3 with the first gate insulating layer GI1 interposed therebetween. The first scan line Sn is extended in one direction traversing the second active pattern A2 and the third active pattern A3, and is formed integrally with the second gate electrode G2 and the third gate electrode G3 to be connected to the second gate electrode G2 and the third gate electrode G3.

The second scan line Sn-1 is spaced apart from the first scan line Sn, is positioned on the fourth active pattern A4 with the first gate insulating layer GI1 interposed therebetween. The second scan line Sn-1 is extended in one direction traversing the fourth active pattern A4, and is formed integrally with the fourth gate electrode G4 to be connected to the fourth gate electrode G4.

The third scan line Sn-2 is spaced apart from the second scan line Sn-1, is positioned on the seventh active pattern A7 with the first gate insulating layer GI1 interposed therebetween. The third scan line Sn-2 is extended in one direction traversing the seventh active pattern A7, and is formed integrally with the seventh gate electrode G7 to be connected to the seventh gate electrode G7.

The light emitting control line EM is spaced apart from the first scan line Sn, and is positioned on the fifth active pattern A5 and the sixth active pattern A6 with the first gate insulating layer GI1 interposed therebetween. The light emitting control line EM is extended in one direction traversing the fifth active pattern A5 and the sixth active pattern A6, and is formed integrally with the fifth gate electrode G5 and the sixth gate electrode G6 to be connected to the fifth gate electrode G5 and the sixth gate electrode G6.

The light emitting control line EM, the third scan line Sn-2, the second scan line Sn-1, the first scan line Sn, the first gate electrode G1, the second gate electrode G2, the third gate electrode G3, the fourth gate electrode G4, the fifth gate electrode G5, the sixth gate electrode G6, and the seventh gate electrode G7 described above are positioned on the same layer and are formed of the same material. Meanwhile, in another exemplary embodiment, alternatively, the light emitting control line EM, the third scan line Sn-2, the second scan line Sn-1, the first scan line Sn, the first gate electrode G1, the second gate electrode G2, the third gate electrode G3, the fourth gate electrode G4, the fifth gate electrode G5, the sixth gate electrode G6, and the seventh gate electrode G7 can be positioned on different layers and be formed of different materials.

The capacitor Cst includes one electrode and the other electrode facing each other with the insulating layer interposed therebetween. One electrode described above can be the capacitor electrode CE, the insulating layer can be the second gate insulating layer GI2, and the other electrode can be the first gate electrode G1. The capacitor electrode CE is positioned on the first gate electrode G1 with the second gate insulating layer GI2 interposed therebetween, and is connected to the driving power supply line ELVDD through the contact hole.

The capacitor electrode CE is positioned on the first gate electrode G1 with the second gate insulating layer GI2 interposed therebetween, and form the capacitor Cst together with the first gate electrode G1. The capacitor electrode CE and first gate electrode G1 can be formed using different metals or the same metal on different layers.

The data line DA is positioned on the first scan line Sn with the third gate insulating layer GI3 interposed therebetween. The data line DA is extended in the other direction traversing the first scan line Sn, and is connected to the second source electrode S2 of the second active pattern A2 through the contact hole CNT. The data line DA is extended while traversing the first scan line Sn, the second scan line Sn-1, the third scan line Sn-2, and the light emitting control line EM.

The driving power supply line ELVDD is spaced apart from the data line DA, and is positioned on the first scan line Sn with the third gate insulating layer GI3 interposed therebetween. The driving power supply line ELVDD is extended in the other direction traversing the first scan line Sn, and is connected to the fifth source electrode S5 of the fifth active pattern A5 connected to the capacitor electrode CE and the first active pattern A1 through the contact hole. The driving power supply line ELVDD is extended while traversing the first scan line Sn, the second scan line Sn-1, the third scan line Sn-2, and the light emitting control line EM.

The gate bridge GB is positioned on the first scan line Sn with the third gate insulating layer GI3 interposed therebetween, and is spaced apart from the driving power supply line ELVDD. The gate bridge GB is connected to each of the third drain electrode D3 of the third active pattern A3 and the fourth drain electrode D4 of the fourth active pattern A4 through the contact hole to thereby be connected to the first gate electrode G1 through the plurality of contact holes CNT included in the plurality of open holes OH. The gate bridge GB includes a stem part ST and a plurality of branch parts BR.

The stem part ST of the gate bridge GB is connected to the third drain electrode D3 of the third active pattern A3 and the fourth drain electrode D4 of the fourth active pattern A4 through the contact hole, and is extended as one line.

The number of branch parts BR of the gate bridge GB is plural, and each of the plurality of branch parts BR is branched from the stem part into each of the plurality of contact holes CNT. Each of the plurality of branch parts BR directly contacts the first gate electrode G1 through each of the plurality of contact holes CNT. In an exemplary embodiment, the number of stem parts ST of the gate bridge GB is one, and the number of branch parts BR of the gate bridge GB is three. However, the described technology is not limited thereto. That is, in another exemplary embodiment, the number of stem parts can be plural, and the number of branch parts can be one, two, or four or more.

The data line DA, the driving power supply line ELVDD, and the gate bridge GB described above are positioned on the same layer and are formed of the same material. Meanwhile, in another exemplary embodiment, alternatively, the data line DA, the driving power supply line ELVDD, and the gate bridge GB can be positioned on different layers and be formed of different materials.

The initialization power supply line Vin is positioned on the second scan line Sn-1, and is connected to the fourth source electrode S4 of the fourth active pattern A4 through the contact hole. The initialization power supply line Vin is positioned on the same layer as a layer on which the first electrode E1 of the OLED is positioned and is formed of the same material as that of the first electrode E1. Meanwhile, in another exemplary embodiment, the initialization power supply line Vin is positioned on a layer different from the layer on which the first electrode E1 is positioned and is formed of a material different from that of the first electrode E1.

The OLED includes the first electrode E1, an organic emission layer OL, and a second electrode E2. The first electrode E1 is connected to the sixth drain electrode D6 of the sixth thin film transistor T6 through the contact hole CNT. The organic emission layer OL is positioned between the first electrode E1 and the second electrode E2. The second electrode E2 is positioned on the organic emission layer OL. One or more of the first electrode E1 and the second electrode E2 can be any one of a light transmitting electrode, a light reflective electrode, and a light transflective electrode, and light emitted from the organic emission layer OL can be emitted toward any one or more of the first electrode E1 and the second electrode E2.

A capping layer covering the OLED can be positioned on the OLED, and a thin film encapsulation layer or an encapsulation substrate can be positioned on the OLED with the capping layer interposed therebetween.

As described above, in the OLED display according to an exemplary embodiment, each of the second gate insulating layer GI2 and the third gate insulating layer GI3 covering the first channel region C1 of the first active pattern A1 includes the plurality of contact holes CNT, which are the plurality of open holes OH overlapped with the first channel region C1 simultaneously (or concurrently) with neighboring to the first channel region C1. Therefore, since heat treatment is performed on the first active pattern A1 in a state in which the second gate insulating layer GI2 covers the first active pattern A1 or in a state in which the second gate insulating layer GI2 and the third gate insulating layer GI3 cover the first active pattern A1, dangling bonds of the first channel region C1 of the first active pattern A1 by the heat treatment are not smoothly removed. Therefore, transistor characteristics of the first thin film transistor T1 including the first active pattern A1 are deteriorated, such that a driving range of a gate voltage (Vgs) applied to the first gate electrode G1 of the first thin film transistor T1, which is a driving thin film transistor, is increased. As a result, since a range of a driving current I_{d} supplied from the first thin film transistor T1 to the OLED is increased, a magnitude of the gate voltage (Vgs) applied to the first gate electrode G1 is changed, thereby making it possible to control light emitted from the OLED to have abundant grays. That is, an OLED display in which display quality of an image displayed by a plurality of OLEDs is improved is provided.

In addition, in the OLED display according to an exemplary embodiment, even though the first channel region C1 of the first active pattern A1 has a form in which it is linearly extended, a driving range of the gate voltage applied to the first gate electrode G1 is increased by the plurality of open holes OH, such that a larger number of first thin film transistors T1 can be formed in a predetermined area. Therefore, a larger number of OLEDs can be formed in the predetermined area, thereby making it possible to manufacture a high resolution OLED display in which a pixel per inch (ppi) is increased.

As described above, even though the high resolution OLED display in which the pixel per inch (ppi) is increased is manufactured, an OLED display in which the driving range of the gate voltage (Vgs) of the first gate electrode G1 of the first thin film transistor T1, which is the driving thin film transistor connected to the OLED of each pixel, is increased, such that grays of light emitted from the OLED are increased, is provided.

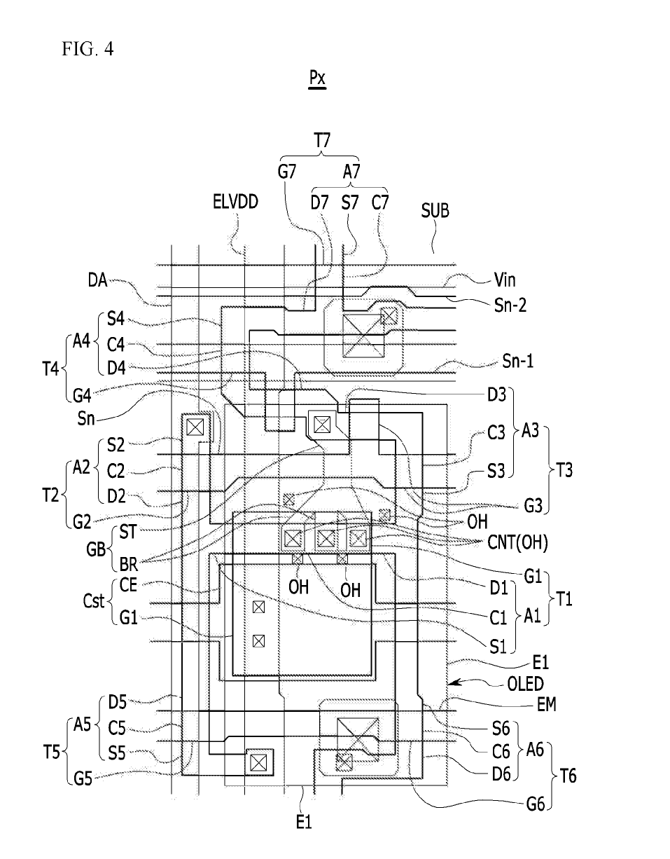

Hereinafter, an OLED display according to another exemplary embodiment will be described with reference to FIG. 4. Hereinafter, components different from those of the OLED display according to an exemplary embodiment described above will be described.

FIG. 4 is a layout view showing one pixel of an OLED display according to another exemplary embodiment.

As shown in FIG. 4, some of the plurality of open holes OH of the OLED display according to another exemplary embodiment are overlapped with the first channel region C1, and the others thereof are not overlapped with the first channel region C1. The plurality of open holes OH include a plurality of contact holes CNT exposing the first gate electrode G1. All of the plurality of contact holes CNT are overlapped with the first channel region C1. The plurality of open holes OH can be selectively formed in each of the first gate insulating layer, the second gate insulating layer, and the third gate insulating layer.

In another exemplary embodiment, the plurality of open holes OH include three contact holes CNT that are overlapped with the first channel region C1 and four open holes OH that are not overlapped with the first channel region C1. However, the described technology is not limited thereto. The number of open holes OH that are not overlapped with the first channel region C1 can be one, two, three, or five or more, in yet another exemplary embodiment.

As described above, even though the high resolution OLED display in which the pixel per inch (ppi) is increased is manufactured, an OLED display in which the driving range of the gate voltage (Vgs) of the first gate electrode G1 of the first thin film transistor T1, which is the driving thin film transistor connected to the OLED of each pixel, is increased by the plurality of open holes OH, such that grays of light emitted from the OLED are increased, is provided.

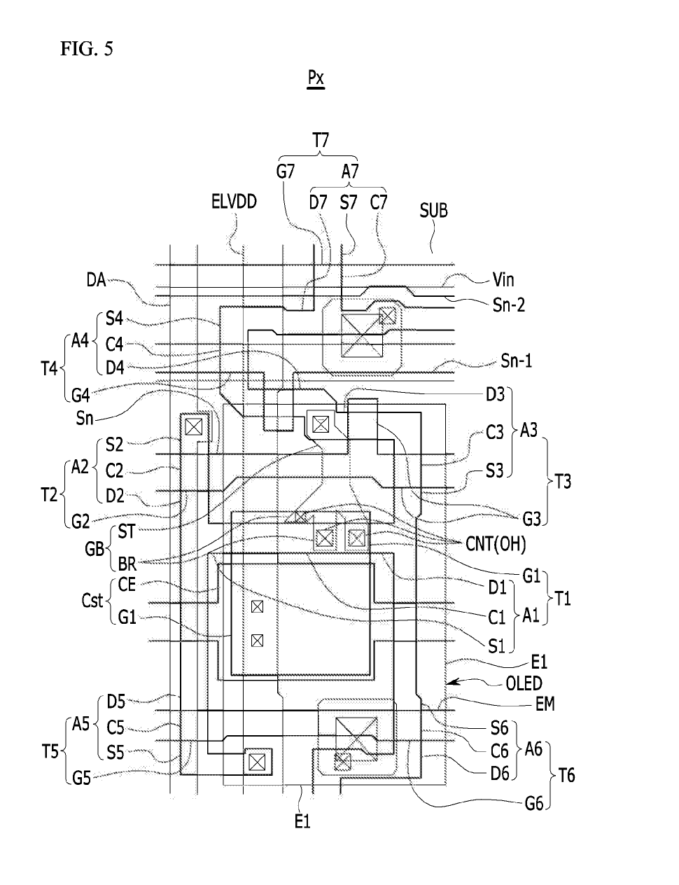

Hereinafter, an OLED display according to another exemplary embodiment will be described with reference to FIG. 5. Hereinafter, components different from those of the OLED display according to an exemplary embodiment described above will be described.

FIG. 5 is a layout view showing one pixel of an OLED display according to another exemplary embodiment.

As shown in FIG. 5, some of the plurality of contact holes CNT included in the plurality of open holes OH of the OLED display according to another exemplary embodiment are overlapped with the first channel region C1, and the others thereof are not overlapped with the first channel region C1. All of the plurality of open holes OH can be the plurality of contact holes CNT exposing the first gate electrode G1. Some of the plurality of contact holes CNT are overlapped with the first channel region C1, and the others thereof are not overlapped with the first channel region C1. The plurality of contact holes CNT can be formed in each of the second gate insulating layer and the third gate insulating layer.

In another exemplary embodiment, the plurality of contact holes CNT include two contact holes CNT that are overlapped with the first channel region C1 and one contact hole CNT that is not overlapped with the first channel region C1. However, the described technology is not limited thereto. That is, in yet another exemplary embodiment, the number of contact holes CNTs that are not overlapped with the first channel region C1 can be plural.

As described above, even though the high resolution OLED display in which the pixel per inch (ppi) is increased is manufactured, an OLED display in which the driving range of the gate voltage (Vgs) of the first gate electrode G1 of the first thin film transistor T1, which is the driving thin film transistor connected to the OLED of each pixel, is increased by the plurality of contact holes CNT, which are the plurality of open holes OH, such that grays of light emitted from the OLED are increased, is provided.

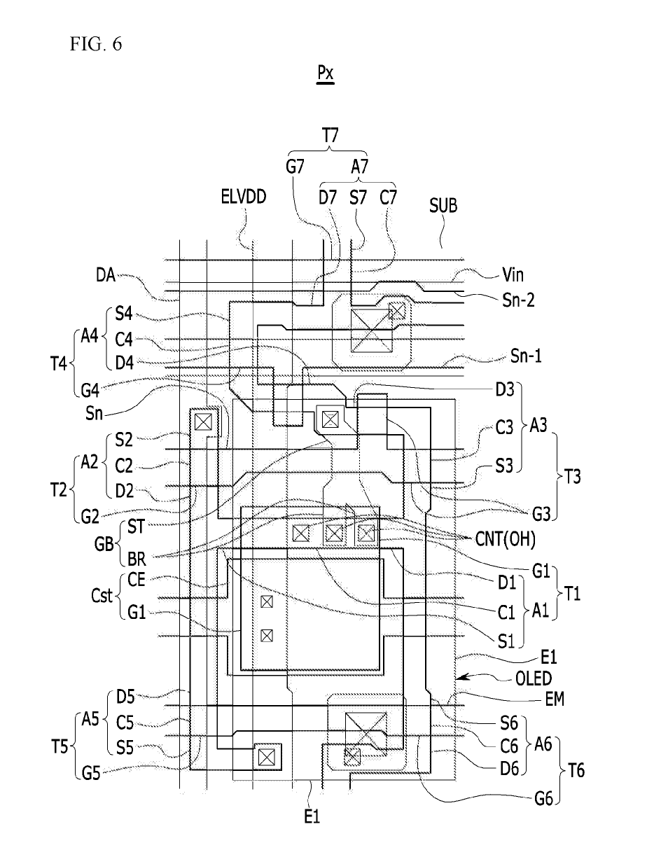

Hereinafter, an OLED display according to another exemplary embodiment will be described with reference to FIG. 6. Hereinafter, components different from those of the OLED display according to an exemplary embodiment described above will be described.

FIG. 6 is a layout view showing one pixel of an OLED display according to another exemplary embodiment.

As shown in FIG. 6, all of the plurality of contact holes CNT included in the plurality of open holes OH of the OLED display according to another exemplary embodiment are overlapped with the first channel region C1. All of the plurality of open holes OH can be the plurality of contact holes CNT exposing the first gate electrode G1. The plurality of contact holes CNT can be formed in each of the second gate insulating layer and the third gate insulating layer.

The number of branch parts BR of the gate bridge GB is plural, and each of the plurality of branch parts BR is branched from the stem part into each of the plurality of contact holes CNT. Each of the plurality of branch parts BR directly contacts the first gate electrode G1 through each of the plurality of contact holes CNT. In an exemplary embodiment, the number of stem part ST of the gate bridge GB is one, the number of branch parts BR of the gate bridge GB is two, and each of the two branch parts BR directly contacts the first gate electrode G1 through each of two of three contact holes CNT.

As described above, even though the high resolution OLED display in which the pixel per inch (ppi) is increased is manufactured, an OLED display in which the driving range of the gate voltage (Vgs) of the first gate electrode G1 of the first thin film transistor T1, which is the driving thin film transistor connected to the OLED of each pixel, is increased by the plurality of contact holes CNT, which are the plurality of open holes OH, such that grays of light emitted from the OLED are increased, is provided.

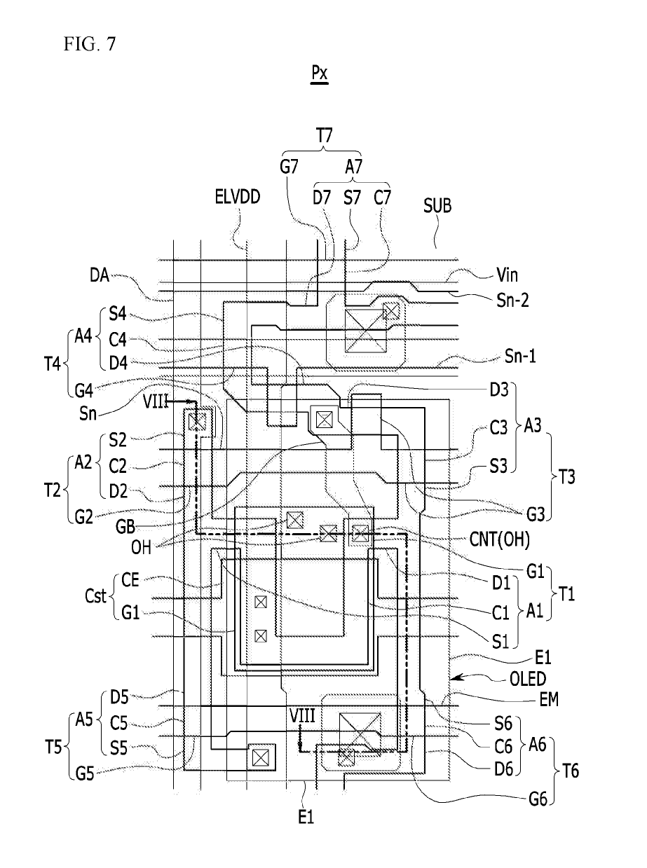

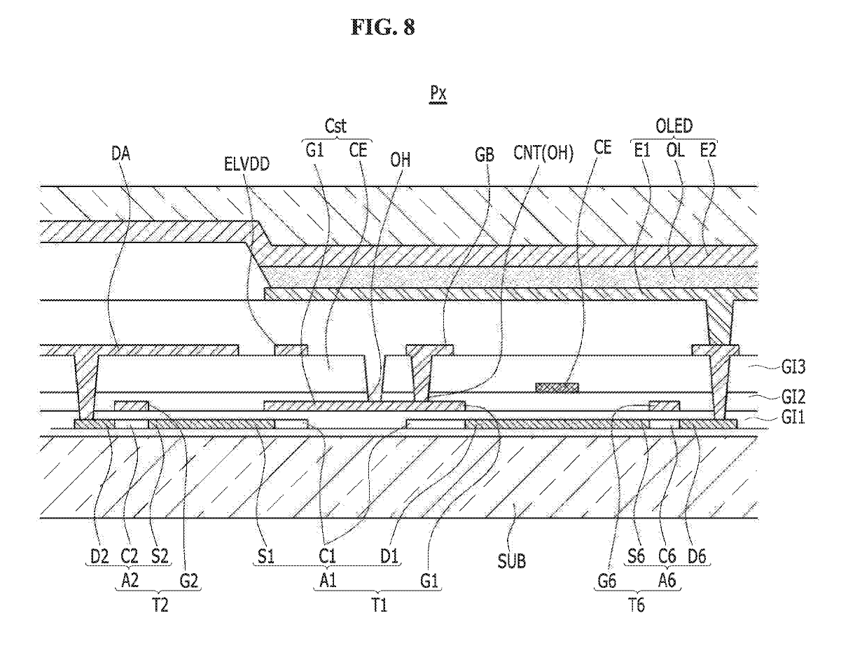

Hereinafter, an OLED display according to another exemplary embodiment will be described with reference to FIGS. 7 and 8. Hereinafter, components different from those of the OLED display according to an exemplary embodiment described above will be described.

FIG. 7 is a layout view showing one pixel of an OLED display according to another exemplary embodiment. FIG. 8 is a cross-sectional view taken along line VIII-VIII of FIG. 7.

As shown in FIGS. 7 and 8, the first channel region C1 of the first active pattern A1 of the first thin film transistor T1 of the OLED display according to another exemplary embodiment has a form in which it is bent once or more and extended. The first channel region C1 is bent once or more and extended within a space overlapped with the first gate electrode G1, which is a limited space, such that the first channel region C1 can be formed at a long length, thereby making it possible to increase the driving range of the gate voltage applied to the first gate electrode G1. Therefore, a magnitude of a gate voltage applied to the first gate electrode G1 is changed in the wide driving range to more minute control grays of the light emitted from the OLED, thereby making it possible to improve quality of an image displayed from the OLED display. A shape of the first channel region C1 of the first active pattern A1 can be variously changed. For example, a shape of the first channel region C1 is changed into various shapes such as a ‘reverse S shape’, an ‘S’ shape, an ‘M’ shape, a ‘W’ shape, and the like.

Some of the plurality of open holes OH are overlapped with the first channel region C1, and the others thereof are not overlapped with the first channel region C1. The plurality of open holes OH include contact holes CNT exposing the first gate electrode G1. The contact holes CNT are overlapped with the first channel region C1. The plurality of open holes OH are formed in each of the second gate insulating layer GI2 and the third gate insulating layer GI3 so as to be in communication with each other.

As described above, an OLED display in which the driving range of the gate voltage (Vgs) of the first gate electrode G1 of the first thin film transistor T1, which is the driving thin film transistor connected to the OLED of each pixel, is further increased by the plurality of open holes OH and the form in which the first channel region C1 of the first active pattern A1 is extended, such that grays of the light emitted from the OLED are further increased, is provided.

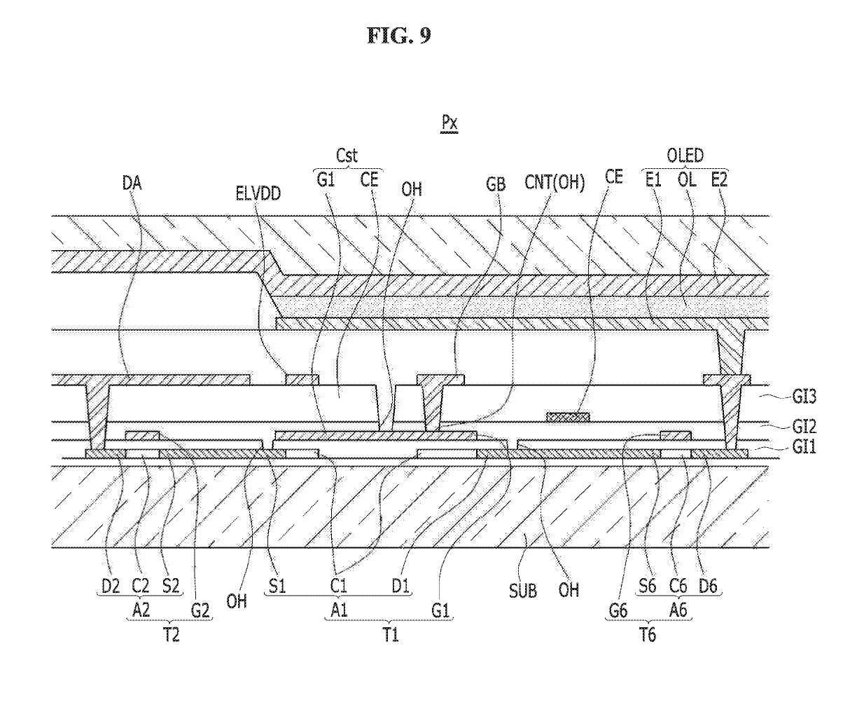

Hereinafter, an OLED display according to another exemplary embodiment will be described with reference to FIG. 9. Hereinafter, components different from those of the OLED display according to another exemplary embodiment described above will be described.

FIG. 9 is a cross-sectional view showing an OLED display according to another exemplary embodiment.

As shown in FIG. 9, some of the plurality of open holes OH of the OLED display according to another exemplary embodiment are overlapped with the first channel region C1, and the others thereof are not overlapped with the first channel region C1. The plurality of open holes OH include contact holes CNT exposing the first gate electrode G1. The contact holes CNT are overlapped with the first channel region C1. Some of the plurality of open holes OH are formed in each of the second gate insulating layer GI2 and the third gate insulating layer GI3 so as to be in communication with each other, and the others thereof are formed in the first gate insulating layer GI1 positioned between the first active pattern A1 and the first gate electrode G1. That is, each of the first gate insulating layer GI1, the second gate insulating layer GI2, and the third gate insulating layer GI3 includes one or more open holes OH.

As described above, in the OLED display according to another exemplary embodiment, each of the first gate insulating layer GI1, the second gate insulating layer GI2, and the third gate insulating layer GI3 covering the first channel region C1 of the first active pattern A1 includes the plurality of open holes OH neighboring to the first channel region C1. Therefore, since heat treatment is performed on the first active pattern A1 in a state in which the first gate insulating layer GI1 covers the first active pattern A1, in a state in which the first gate insulating layer GI1 and the second gate insulating layer GI2 cover the first active pattern A1, or in a state in which the first gate insulating layer GI1, the second gate insulating layer GI2, and the third gate insulating layer GI3 cover the first active pattern A1, dangling bonds of the first channel region C1 of the first active pattern A1 by the heat treatment are not smoothly removed. Therefore, transistor characteristics of the first thin film transistor T1 including the first active pattern A1 are deteriorated, such that a driving range of a gate voltage (Vgs) applied to the first gate electrode G1 of the first thin film transistor T1, which is a driving thin film transistor, is increased. As a result, since a range of a driving current I_{d} supplied from the first thin film transistor T1 to the OLED is increased, a magnitude of the gate voltage (Vgs) applied to the first gate electrode G1 is changed, thereby making it possible to control light emitted from the OLED to have abundant grays. That is, an OLED display in which display quality of an image displayed by a plurality of OLEDs OLED is improved is provided.

As described above, an OLED display in which the driving range of the gate voltage (Vgs) of the first gate electrode G1 of the first thin film transistor T1, which is the driving thin film transistor connected to the OLED of each pixel, is further increased by the plurality of open holes OH, such that grays of the light emitted from the OLED are further increased, is provided.

While the inventive technology has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. An organic light-emitting diode (OLED) display comprising:
a substrate;
a first thin film transistor (TFT) formed over the substrate and including a first active pattern, wherein the first active pattern includes a channel region and a first gate electrode formed over the channel region;
a gate insulating layer formed over the first active pattern and including a plurality of openings formed adjacent to the channel region of the first active pattern; and
an OLED electrically connected to the first active pattern.

2. The OLED display of claim 1, wherein at least one of the openings overlap the channel region.

3. The OLED display of claim 2, wherein at least one of the openings does not overlap the channel region.

4. The OLED display of claim 1, wherein the gate insulating layer covers the first gate electrode.

5. The OLED display of claim 4, wherein the openings include one or more contact holes formed over the first gate electrode.

6. The OLED display of claim 5, wherein more than one of the contact holes are formed, and wherein at least one of the contact holes overlap the channel region of the first active pattern.

7. The OLED display of claim 5, wherein more than one of the contact holes are formed, wherein some of the contact holes overlap the channel region, and wherein the other contact holes do not overlap the channel region.

8. The OLED display of claim 5, further comprising:
a second thin film transistor including i) a second active pattern electrically connected to a first end portion of the first active pattern and ii) a second gate electrode formed over the second active pattern;
a data line formed over the gate insulating layer and electrically connected to the second active pattern;
a third thin film transistor including i) a third active pattern electrically connected to a second end portion of the first active pattern and ii) a third gate electrode formed over the third active pattern; and
a gate bridge formed over the gate insulating layer, configured to electrically connect the third active pattern to the first gate electrode, and directly connected to the first gate electrode through the contact hole.

9. The OLED display of claim 8, wherein more than one of the contact holes are formed, and wherein the gate bridge includes:
one stem part connected to the third active pattern; and
a plurality of branch parts branching from the stem part into each of the contact holes to each contact the first gate electrode via the contact holes.

10. The OLED display of claim 8, further comprising:
a first scan line formed over the second and third active patterns and electrically connected to the second gate electrode and the third gate electrode; and
a driving power supply line formed adjacent to the data line on the first scan line and electrically connected to the first active pattern.

11. The OLED display of claim 10, further comprising a capacitor electrode electrically connected to the driving power supply line, formed over the first gate electrode, and overlapping the first gate electrode to form a capacitor together with the first gate electrode.

12. The OLED display of claim 11, wherein each of the first gate electrode and the capacitor electrode is formed of a metal.

13. The OLED display of claim 10, further comprising:
a fourth thin film transistor electrically connected to the third active pattern and including a fourth active pattern electrically connected to the first gate electrode via the gate bridge and a fourth gate electrode formed over the fourth active pattern;
a second scan line formed over the fourth active pattern and electrically connected to the fourth gate electrode; and
an initialization power supply line electrically connected to the fourth active pattern.

14. The OLED display of claim 13, further comprising:
a fifth thin film transistor including i) a fifth active pattern configured to electrically connect the first active pattern to the driving power supply line and ii) a fifth gate electrode formed over the fifth active pattern;
a sixth thin film transistor including i) a sixth active pattern configured to electrically the first active pattern to the OLED and ii) a sixth gate electrode formed over the sixth active pattern; and
a light emitting control line formed over each of the fifth active pattern and the sixth active pattern and electrically connected to the fifth and sixth gate electrodes.

15. The OLED display of claim 14, further comprising:
a seventh thin film transistor including a seventh active pattern electrically connected to the fourth active pattern and a seventh gate electrode formed over the seventh active pattern; and
a third scan line formed over the seventh active pattern and electrically connected to the seventh gate electrode.

16. The OLED display of claim 1, wherein the gate insulating layer is interposed between the first active pattern and the first gate electrode.

17. The OLED display of claim 1, wherein two or more of the openings do not overlap the channel region.

18. The OLED display of claim 1, wherein the gate insulating layer includes: a first gate insulating layer covering the channel region of the first active pattern and ii) second and third gate insulating layers formed over the first gate insulating layer and the first gate electrode, and wherein the openings are formed in the second and third gate insulating layers.

19. The OLED display of claim 1, wherein the first active pattern further includes source and drain electrodes, and wherein the channel region of the first active pattern linearly extending from the source electrode to the drain electrode has a substantially uniform width.

20. The OLED display of claim 1, wherein the channel region of the first active pattern is bent at least once.
